(19) United States
(12) Patent Application Publication
(10) Pub. No.: US 2023/0013637 A1
(43) Pub. Date: Jan. 19, 2023

(54) SUBSTRATE SUPPORT STRUCTURES AND METHODS OF MAKING SUBSTRATE SUPPORT STRUCTURES

(71) Applicant: ASM IP Holding B.V., Almere (NL)

(72) Inventors: Joaquin Aguilar Santillan, Gilbert, AZ (US); Shanker Kuttath, Austin, TX (US); Hong Gao, San Jose, CA (US)

(21) Appl. No.: 17/857,344

(22) Filed: Jul. 5, 2022

Related U.S. Application Data
(60) Provisional application No. 63/219,245, filed on Jul. 7, 2021.
(60) Provisional application No. 63/283,709, filed on Nov. 29, 2021.

(51) Int. Cl. C23C 16/458; C04B 35/581; C23C 16/455; C04B 35/505; C04B 35/64; C23C 16/40

(52) U.S. Cl. CPC C23C 16/4581; C04B 35/581; C23C 16/45553; C04B 35/505; C04B 35/64; C23C 16/403; C23C 16/405

(57) ABSTRACT

A substrate support structure includes a substrate support structure body formed from a ceramic composite and having a first surface, a second surface spaced apart from the first surface, and a periphery spanning the first surface and the second surface of the substrate support structure body. The first surface, the second surface, and the periphery of the substrate support structure body are defined by the ceramic composite. The ceramic composite includes two or more of a (a) an aluminum nitride (AlN) constituent, (b) an aluminum oxynitride (Al_{2.81}O_{3.56}N_{0.44}, AlON) constituent, (c) an alpha-alumina (α-Al₂O₃) constituent, (d) a yttrium alumina garnet (Y₃Al₅O₁₂, YAG) constituent, (e) a yttrium alumina monoclinic (Y₄Al₂O₉, YAM) constituent, (f) a yttrium alumina perovskite (YAlO₃, YAP) constituent, and (g) a yttrium oxide (Y₂O₃) constituent. Semiconductor processing systems and methods of making substrate support structures are also described.

### RELATED APPLICATIONS

This application claims priority to U.S. Provisional Patent Application Ser. No. 63/219,245 filed Jul. 7, 2021 and titled ESC CHUCKS BASED ON CERAMIC SYSTEM AIN-AI2O3-Y2O3: MATERIAL CONDITIONING, PROCESS OF MANUFACTURE AND COMPOSITION; and U.S. Provisional Patent Application Ser. No. 63/283,709 filed Nov. 29, 2021 and titled SUBSTRATE SUPPORT STRUCTURES AND METHODS OF MAKING SUBSTRATE SUPPORT STRUCTURES, the disclosures of which are hereby incorporated by reference in their entirety.

### FIELD OF INVENTION

The present disclosure relates generally to depositing films onto substrates. More particularly, the present disclosure relates to supporting substrates during the deposition of films onto substrates during the fabrication of semiconductor devices.

### BACKGROUND OF THE DISCLOSURE

Semiconductor devices are commonly fabricated by depositing thin films onto substrates, such as using chemical vapor deposition (CVD) like atomic layer deposition (ALD) and plasma-enhanced atomic layer deposition (PEALD) techniques. ALD is a surface-controlled layer-by-layer process that results in the deposition of thin films one atomic layer at a time during a sequence of reaction cycles. PEALD is similar to ALD and additionally employs dissociated reactant ions and molecules to sequentially deposition the thin film one atomic layer at a time during the sequence of reaction cycles. Film deposition in either technique generally involves supporting the substrate on chuck, heating the substrate to a desired deposition temperature, and introducing a reactant into the reaction chamber cyclically to form a film on the substrate. The chuck may be formed from a ceramic material having electrical properties that allow the substrate to be electrostatically fixed to the chuck during deposition of the film onto the substrate.

In some film deposition processes, the deposition temperature employed in the film deposition process may limit the expected service life of the chuck. For example, thermal stress within the ceramic material forming the chuck associated with a desired film deposition temperatures may cause cracking within the ceramic material forming the chuck, potentially requiring periodic replacement of the chuck. Temperature ramping of the substrate to the film deposition temperature may induce thermal stress within the ceramic material forming the chuck may also cause cracking, also potentially requiring periodic replacement of the chuck. And thermal cycling of the chuck associated with sequential film deposition events within the reaction chamber may further cause cracking within the ceramic material forming the chuck, further driving a need to periodically replace the chuck.

To limit the need for periodic chuck replacement, the film deposition temperature employed in some ALD and PEALD processes may be limited according to the ceramic material forming the chuck, for example to less than 350° C., or less than 300° C., or even less than 250° C., the film deposition temperature employed by the film deposition process limiting (or eliminating) the need to periodically replace the chuck. While generally acceptable for its intended purpose, limiting film deposition temperature due to temperature limitations associated with the ceramic material forming the chuck may, in some semiconductor processing systems, reduce throughput.

Such systems and methods have generally been acceptable for their intended purpose. However, there remains a need for improved substrate support structures, semiconductor processing systems, and methods of making substrate support structures. The present disclosure provides a solution to one or more these needs.

### SUMMARY OF THE DISCLOSURE

A substrate support structure includes a substrate support structure body formed from a ceramic composite and having a first surface, a second surface spaced apart from the first surface, and a periphery spanning the first surface to the second surface. The first surface, the second surface, and the periphery of the substrate support structure body are defined by the ceramic composite. The ceramic composite includes two or more of (a) aluminum nitride (AlN), (b) aluminum oxynitride (Al_{2.81}O_{3.56}N_{0.44}, AlON), (c) alpha-alumina (α-Al₂O₃), (d) yttrium alumina garnet (Y₃Al₅O₁₂, YAG), (e) yttrium alumina monoclinic (Y₄Al₂O₉, YAM), (f) yttrium alumina perovskite (YAlO₃, YAP), and (g) yttrium oxide (Y₂O₃).

In addition to one or more of the features described above, or as an alternative, further examples of the substrate support structure may include that the ceramic composite consists essentially of or consists of aluminum nitride (AlN) and yttrium oxide (Y₂O₃).

In addition to one or more of the features described above, or as an alternative, further examples of the substrate support structure may include that the ceramic composite has more aluminum nitride (AlN) than yttrium oxide (Y₂O₃).

In addition to one or more of the features described above, or as an alternative, further examples of the substrate support structure may include that the ceramic composite has between about 35% and about 65% aluminum nitride (AlN).

In addition to one or more of the features described above, or as an alternative, further examples of the substrate support structure may include that the ceramic composite consists essentially of or consists of aluminum nitride (AlN), yttrium alumina monoclinic (Y₄Al₂O₉, YAM), and yttrium oxide (Y₂O₃).

In addition to one or more of the features described above, or as an alternative, further examples of the substrate support structure may include that the substrate support structure body includes a coating.

In addition to one or more of the features described above, or as an alternative, further examples of the substrate support structure may include that the coating consists of the ceramic composite or of titanium dioxide (TiO₂).

In addition to one or more of the features described above, or as an alternative, further examples of the substrate support structure may include that the ceramic composite has more aluminum nitride (AlN) than yttrium alumina monoclinic (Y₄Al₂O₉, YAM).

In addition to one or more of the features described above, or as an alternative, further examples of the substrate support structure may include that the ceramic composite has between about 25% and about 40% aluminum nitride (AlN), between about 20% and about 30% yttrium alumina monoclinic (Y₄Al₂O₉, YAM), and between about 30% and about 55% yttrium oxide (Y₂O₃).

In addition to one or more of the features described above, or as an alternative, further examples of the substrate support structure may include that the ceramic composite consists essentially of or consists of aluminum nitride (AlN), yttrium alumina monoclinic (Y₄Al₂O₉, YAM), and yttrium alumina perovskite (YAlO₃, YAP).

In addition to one or more of the features described above, or as an alternative, further examples of the substrate support structure may include that the ceramic composite has more yttrium alumina perovskite (YAlO₃, YAP) than aluminum nitride (AlN).

In addition to one or more of the features described above, or as an alternative, further examples of the substrate support structure may include that the ceramic composite has between about 15% and about 30% aluminum nitride (AlN), between about 15% and about 45% yttrium alumina monoclinic (Y₄Al₂O₉, YAM), and between about 30% and about 70% yttrium alumina perovskite (YAlO₃, YAP).

In addition to one or more of the features described above, or as an alternative, further examples of the substrate support structure may include that the ceramic composite consists essentially of or consists of aluminum nitride (AlN), yttrium alumina garnet (Y₃Al₅O₁₂, YAG), and yttrium alumina perovskite (YAlO₃, YAP).

In addition to one or more of the features described above, or as an alternative, further examples of the substrate support structure may include that the ceramic composite has more yttrium alumina garnet (Y₃Al₅O₁₂, YAG) than aluminum nitride (AlN). The bulk composite material may have more yttrium alumina garnet (Y₃Al₅O₁₂, YAG) than yttrium alumina perovskite (YAlO₃, YAP).

In addition to one or more of the features described above, or as an alternative, further examples of the substrate support structure may include that the ceramic composite has between about 15% and about 35% aluminum nitride (AlN), between about 40% and about 50% yttrium alumina garnet (Y₃Al₅O₁₂, YAG), and about 20% and about 40% yttrium alumina perovskite (YAlO₃, YAP).

In addition to one or more of the features described above, or as an alternative, further examples of the substrate support structure may include that the ceramic composite consists essentially of or consists of aluminum nitride (AlN), aluminum oxynitride (Al_{2.81}O_{3.56}N_{0.44}, AlON), and yttrium alumina garnet (Y₃Al₅O₁₂, YAG).

In addition to one or more of the features described above, or as an alternative, further examples of the substrate support structure may include that the aluminum oxynitride (Al_{2.81}O_{3.56}N_{0.44}, AlON) has a γ-spinel crystalline structure.

In addition to one or more of the features described above, or as an alternative, further examples of the substrate support structure may include that the ceramic composite has more aluminum oxynitride (Al_{2.81}O_{3.56}N_{0.44}, AlON) than each of aluminum nitride (AlN) and yttrium alumina garnet (Y₃Al₅O₁₂, YAG).

In addition to one or more of the features described above, or as an alternative, further examples of the substrate support structure may include that the ceramic composite has between about 25% and about 30% aluminum nitride (AlN), between about 55% and about 60% aluminum oxynitride (Al_{2.81}O_{3.56}N_{0.44}, AlON), and between about 10% and about 20% yttrium alumina garnet (Y₃Al₅O₁₂, YAG).

In addition to one or more of the features described above, or as an alternative, further examples of the substrate support structure may include that the ceramic composite consists essentially of or consists of aluminum oxynitride (Al_{2.81}O_{3.56}N_{0.44}, AlON) and yttrium alumina garnet (Y₃Al₅O₁₂, YAG).

In addition to one or more of the features described above, or as an alternative, further examples of the substrate support structure may include that the ceramic composite has more aluminum oxynitride (Al_{2.81}O_{3.56}N_{0.44}, AlON) than yttrium alumina garnet (Y₃Al₅O₁₂, YAG).

In addition to one or more of the features described above, or as an alternative, further examples of the substrate support structure may include that the ceramic composite has between about 60% and about 95% aluminum oxynitride (Al_{2.81}O_{3.56}N_{0.44}, AlON), and between about 5% and about 40% yttrium alumina garnet (Y₃Al₅O₁₂, YAG).

In addition to one or more of the features described above, or as an alternative, further examples of the substrate support structure may include that the ceramic composite consists essentially of or consists of aluminum oxynitride (Al_{2.81}O_{3.56}N_{0.44}, AlON), alpha-alumina (alpha-alumina (α-Al₂O₃), and yttrium alumina garnet (Y₃Al₅O₁₂, YAG).

In addition to one or more of the features described above, or as an alternative, further examples of the substrate support structure may include that the ceramic composition forming the substrate support structure includes titanium dioxide (TiO₂).

In addition to one or more of the features described above, or as an alternative, further examples of the substrate support structure may include that the substrate support structure is an electrostatic chuck or a wafer tray configured to seat a substrate during deposition of a material layer onto the substrate within a process chamber of a semiconductor processing system.

A semiconductor processing system is provided. The semiconductor processing system includes a precursor source, a remote plasma unit connected to the precursor source, and a process chamber with a showerhead and a substrate support structure as described above. The showerhead fluidly couples the substrate support structure to the precursor source through the remote plasma unit.

A method of making a substrate support structure is provided. The includes intermixing mixing an aluminum oxide (Al₂O₃) powder with an yttrium oxide (Y₂O₃) powder and an aluminum nitride (AlN) powder and forming a powder compact from the intermixed aluminum oxide (Al₂O₃) powder, yttrium oxide (Y₂O₃) powder, and aluminum nitride (AlN) powder. The powder compact is sintered for a predetermined sintering period at a predetermined sintering temperature and at a predetermined sintering pressure. The sintered powder compact is thereafter cooled to form a ceramic composite including two or more constituents selected from a group including (a) an aluminum nitride (AlN) constituent, (b) an aluminum oxynitride (Al_{2.81}O_{3.56}N_{0.44}, AlON) constituent, (c) an alpha-alumina (α-Al₂O₃) constituent, (d) a yttrium alumina garnet (Y₃Al₅O₁₂, YAG) constituent, (e) a yttrium alumina monoclinic (Y₄Al₂O₉, YAM) constituent, (f) a yttrium alumina perovskite (YAlO₃, YAP) constituent, and (g) a yttrium oxide (Y₂O₃) constituent.

In addition to one or more of the features described above, or as an alternative, further examples of the method may include that the powder compact includes between about 0.02 Mol % and about 85 Mol % aluminum oxide (Al₂O₃), between about 10 Mol % and about 65 Mol % yttrium oxide (Y₂O₃), and between about 5 Mol % and about 65 Mol % aluminum nitride (AlN).

In addition to one or more of the features described above, or as an alternative, further examples of the method may include that the predetermined sintering temperature is between about 1500° C. and about 1750° C., or about 1525° C. and about 1725° C., or about 1550° C. and about 1700° C.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a side view of a semiconductor processing system including a process module with a substrate support structure in accordance with the present disclosure, showing the substrate support structure in a process module for depositing material layers onto substrates;

FIG. 2 is schematic view of the process chamber and substrate support structure of FIG. 1 according to an example, showing the ceramic composite of the substrate support structure communicating heat to a substrate during deposition of a material layer onto the substrate;

FIG. 3 is schematic view of the substrate support structure of FIG. 1 according to an example, showing through-holes defined in the substrate support structure as well as a heater element and a coolant circuit embedded within the bulk ceramic composite forming the substrate support structure;

FIGS. 4-11 are schematic views of ceramic composites forming the substrate support structure of FIG. 1 according to examples, showing constituents of the ceramic composites selected for depositing material layers at relatively high deposition temperatures; and

FIG. 12 is a block diagram of a method of making a substrate support structure, showing operations of the method according to an illustrative and non-limiting example.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

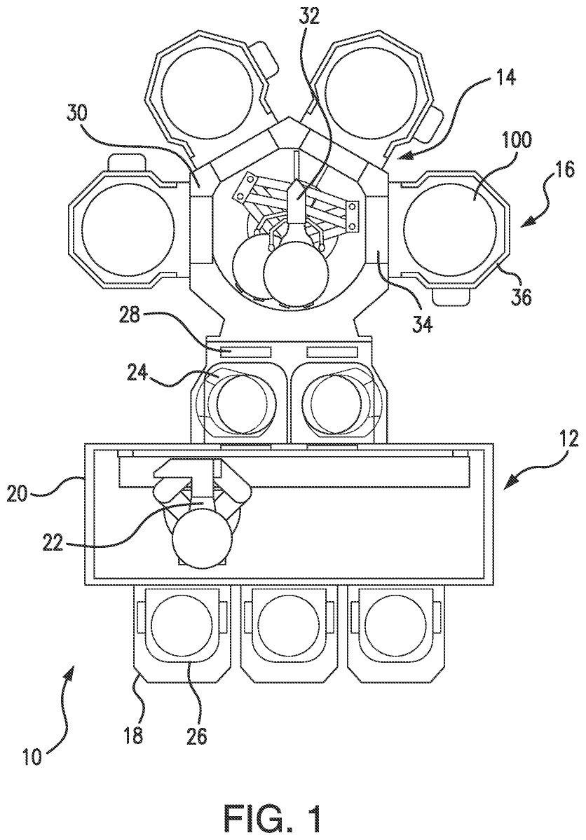

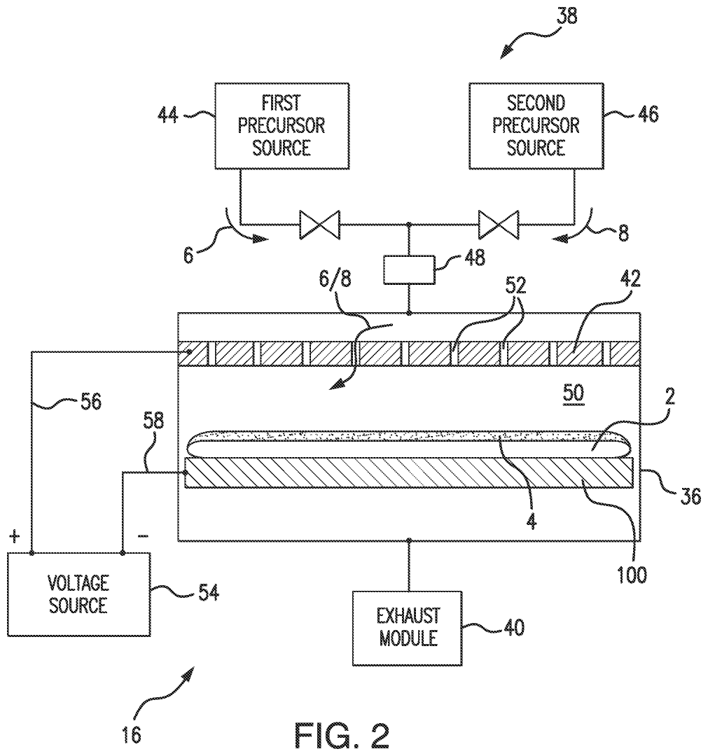

Reference will now be made to the drawings wherein like reference numerals identify similar structural features or aspects of the subject disclosure. For purposes of explanation and illustration, and not limitation, a substrate support structure, e.g., a chuck or heater, in accordance with the present disclosure is shown in FIG. 1 and is designated generally by reference character 100. Other examples of substrate support structures, semiconductor processing systems having substrate support structures, and methods of making substrate support structures, in accordance with the present disclosure, or aspects thereof, are provided in FIGS. 2-12, as will be described. The substrate support structures described herein can be used to support substrates during the fabrication of semiconductor devices, such as during the deposition of material layers onto substrates at high temperatures using chemical vapor deposition (CVD) techniques like atomic layer deposition (ALD) and plasma-enhanced atomic layer deposition (PEALD) techniques, though the present disclosure is not limited to any particular deposition technique or to high temperature material layer deposition techniques in general.

Referring to FIG. 1, a semiconductor processing system 10 is shown. The semiconductor processing system 10 includes a front-end module 12, a back-end module 14, and a process module 16 with the substrate support structure 100. The front-end module 12 is configured for interfacing the semiconductor processing system 10 with the external environment and in this respect includes a load port 18, an enclosure 20, a front-end robot 22, and a load lock 24. The load port 18 is configured to seat a pod 26, e.g., a front-opening unified pod (FOUP), housing one or more substrates, e.g., a substrate 2 (shown in FIG. 2), for processing within the process module 16. The front-end robot 22 is arranged within the enclosure 20, is movable within the enclosure 20 relative to the load port 18, and is configured to transfer substrates between the load port 18 and the load lock 24. The load lock 24 is connected to the enclosure 20, couples the front-end module 12 to the back-end module 14, and is configured to support one more substrates during transfer of the substrates between the front-end module 12 and the back-end module 14. In certain examples, the load lock 24 may include a chill plate for cooling a substrate during transfer between the back-end module 14 and the front-end module 12. In accordance with certain examples, the load lock 24 may be fluidly coupled with a vacuum and venting arrangement to interface atmospheric pressure environment within the enclosure 20 with an evacuated environment maintained in the back-end module 14.

The back-end module 14 is configured for moving substrates between one or more process module 16 and in this respect includes a transfer chamber gate valve 28, a transfer chamber 30, and a back-end robot 32. The transfer chamber gate valve 28 connects the transfer chamber 30 to the load lock 24 and is configured to selectively separate the environment within the load lock 24 from the environment within the transfer chamber 30. The transfer chamber 30 is connected to the load lock 24, couples the process module 16 to the front-end module 12, and houses therein the back-end robot 32. The back-end robot 32 arranged within the transfer chamber 30, is supported for movement relative to the transfer chamber 30, and is configured for transferring substrates between the load lock 24 and the process module 16.

The process module 16 is configured for depositing a material layer 4 (shown in FIG. 2) using a first precursor 6 (shown in FIG. 2) and/or a second precursor 8 (shown in FIG. 2) and in this respect includes a process module gate valve 34, a chamber body 36, and the substrate support structure 100. The process module gate valve 34 connects the chamber body 36 to the back-end module 14 and is configured to selectively separate the environment within chamber body 36 and the environment within the transfer chamber 30. The chamber body 36 is coupled to the transfer chamber 30 by the process module gate valve 34, seats therein the substrate support structure 100, and cooperates with a gas delivery system 38 (shown in FIG. 2) to deposit material layers onto substrates supported on the substrate support structure 100. In certain examples, the process module 16 may be configured to deposit material layers onto substrates using an ALD technique. In accordance with certain examples, the process module 16 may be configured to deposit material layers onto substrates using a PEALD technique. It is also contemplated that, in accordance with certain examples, the process module 16 may be configured for the selective removal of a material layer from substrates, e.g., using a precleaning technique. Although four (4) process modules are shown in the illustrated example, it is to be understood and appreciated that the semiconductor processing system 10 may have fewer or additional process modules and remain within the scope of the present disclosure.

With reference to FIG. 2, the process module 16 is shown. The process module 16 couples the gas delivery system 38 to an exhaust module 40 and includes a showerhead 42. The gas delivery system 38 includes a first precursor source 44 and a second precursor source 46. The first precursor source 44 is configured to provide the first precursor 6 to the chamber body 36. The second precursor source 46 is configured to provide the second precursor 8 to the chamber body 36. In certain examples, the process module 16 may include a remote plasma unit 48. In such examples the remote plasma unit 48 may couple (e.g., fluidly couple) one or more of the first precursor source 44 and the second precursor source 46 to the chamber body 36. Examples of suitable remote plasma units include HMPX60Q-MKS remote plasma sources, available from MKS Instruments, Inc. of Andover, Mass.

The showerhead 42 and the substrate support structure 100 are arranged within an interior 50 of the chamber body 36 and are spaced apart from one another. In this respect the showerhead 42 has an aperture array 52, is fixed within the interior of the chamber body 36, and separates the substrate support structure 100 from the gas delivery system 38 such that the aperture array 52 (and thereby the showerhead 42) fluidly couples the substrate support structure 100 to the gas delivery system 38, which may include a precursor source. The substrate support structure 100 is also fixed within the interior of the chamber body 36, is spaced apart from the showerhead 42 by a process space, and separates the showerhead 42 from the exhaust module 40. In certain examples, the process module 16 may include a voltage source 54. In such examples the voltage source 54 may be configured to introduce a voltage difference between components within the process module 16, e.g., for electrostatic chucking of the substrate 2 and/or to direct radical specie within the interior 50 of the chamber body 36, using a first lead 56 electrically connected to the showerhead 42 and a second lead 58 electrically connected to the substrate support structure 100.

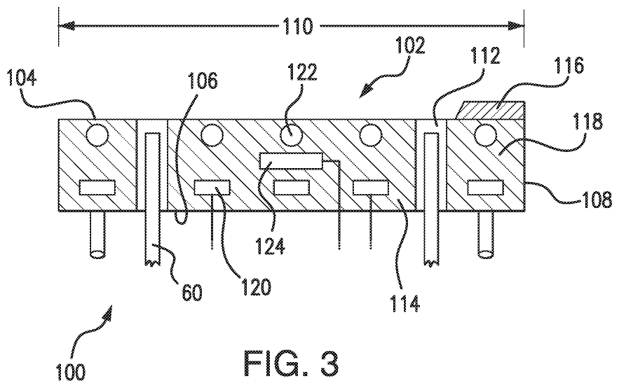

With reference to FIG. 3, the substrate support structure 100 is shown. The substrate support structure 100 includes a substrate support structure body 102 with an upper surface 104, a lower surface 106, and a periphery 108. The upper surface 104 opposes the showerhead 42 (shown in FIG. 2). The lower surface 106 is spaced apart from the upper surface 104 by a thickness the substrate support structure body 102. The periphery 108 spans the upper surface 104 and the lower surface 106, extends circumferentially about substrate support structure body 102, and has a diameter 110. In certain examples, the diameter may be greater than about 300 millimeters, the substrate support structure 100 thereby arranged to seat a substrate including a 300-millimeter silicon wafer. In accordance with certain examples, the substrate support structure body 102 may define a plurality of through holes 112 extending therethrough. In such examples a respective lift pin 60 may be movably supported therein for seating and unseating substrates, e.g., the substrate 2 (shown in FIG. 2), from the upper surface 104 of the substrate support structure body 102. It is contemplated that the substrate support structure body 102 be formed from a ceramic composite 114.

The ceramic composite 114 is formed from a plurality of constituent ceramic materials and is a bulk material. In this respect the substrate support structure 100 may consists of (or consists essentially of) the ceramic composite 114. For example, the ceramic composite 114 may form more than 50% of the substrate support structure body 102 by weight or volume, or more than 70% of the substrate support structure body 102 by weight or volume, or even more than 90% of the substrate support structure body 102 by weight or volume. In certain examples, the ceramic composite 114 may define the upper surface 104. In accordance with certain examples, the ceramic composite 114 may define the lower surface 106. In further examples, the ceramic composite 114 may extend contiguously (or monolithically) between the upper surface 104 and the lower surface 106 of the substrate support structure body 102 and/or contiguously between diametrically opposite sides of periphery 108 of the substrate support structure body 102. It is also contemplated that, in accordance with certain examples, one or more of the upper surface 104, the lower surface 106, and/or the periphery 108 of substrate support structure body 102 may have a coating 116 thereon. In such examples the coating 116 may include a ceramic material 118. In certain examples, the ceramic material 118 forming the coating 116 may include (e.g., consist of or consist essentially of) the ceramic composite 114. In accordance with certain examples, the ceramic material 118 forming the coating may include (e.g., consist of or consist essentially of) titanium dioxide (TiO₂). The ceramic material 118 may be deposited onto the bulk material forming the substrate support structure body 102 using an ALD technique.

In certain examples, the substrate support structure body 102 may include one or more of a heater element 120, a coolant circuit 122, and/or a temperature sensor 124. The heater element 120 may be embedded within the substrate support structure body 102, e.g., such that the heater element 120 is surrounded by the ceramic composite 114, to communicate heat to the upper surface 104 of the substrate support structure body 102 via the ceramic composite 114. The heater element 120 may be a resistive heater element, the heater element 120 configured to resistively heat the substrate 2 (shown in FIG. 2) supported on the upper surface 104 of the substrate support structure body 102. In this respect source and return leads may extend from the substrate support structure body 102 for electrically connecting the heater element 120 to a power source. Although a singular heater element 120 is shown and described herein, it is to be understood and appreciated that the substrate support structure body 102 may have more than one heater element (or a heater element array) and remain within the scope of the present disclosure.

The coolant circuit 122 may be embedded within the substrate support structure body 102, e.g., such that the heater element 120 is surrounded by ceramic composite 114, the coolant circuit 122 configured to transfer heat between the upper surface 104 of the substrate support structure body 102 and a coolant flowing through coolant circuit 122 via the ceramic composite 114. In this respect the substrate support structure body 102 have an inlet conduit and an outlet conduit for circulating a coolant therethrough, such as glycol or nitrogen by way of non-limiting examples. Although a singular coolant circuit 122 is shown and described herein, it is to be understood and appreciated that the substrate support structure body 102 may have two or more coolant circuits and remain within the scope of the present disclosure. Further, although shown in FIG. 3 as arranged between the heater element 120 and the upper surface 104 of the substrate support structure body 102, it is to be understood and appreciated that the coolant circuit 122 may be arranged between the heater element 120 and the lower surface 106 of the substrate support structure body 102 and remain within the scope of the present disclosure.

The temperature sensor 124 may be embedded within the substrate support structure body 102, e.g., such that the temperature sensor 124 is surrounded by ceramic composite 114, the temperature sensor 124 thereby configured generate a signal including information indicative of temperature within the substrate support structure body 102 at the location of the temperature sensor 124. In this respect the substrate support structure body 102 have one or more temperature sensor lead extending from the substrate support structure body 102, the temperature sensor lead configured to convey the signal to an external device. Although a singular temperature sensor 124 is shown and described herein, it is to be understood and appreciated that the substrate support structure body 102 may two or more temperature sensors, or temperature sensor arrays, and remain within the scope of the present disclosure. Further, although shown in FIG. 3 as arranged between the heater element 120 and the upper surface 104 of the substrate support structure body 102, it is to be understood and appreciated that the temperature sensor 124 may be arranged between the heater element 120 and the lower surface 106 of the substrate support structure body 102 and remain within the scope of the present disclosure.

With continuing reference to FIG. 2, deposition of the material layer 4 onto the substrate 2 is accomplished by transferring the substrate 2 into the interior of the chamber body 36, seating the substrate 2 onto the substrate support structure 100, and heating the substrate 2 to a predetermined deposition temperature. Deposition of the material layer 4 onto the substrate 2 is further accomplished by providing the first precursor 6 and/or the second precursor 8 to the interior 50 of the chamber body 36, e.g., sequentially and/or by dissociation of ions and molecules of the precursor 6 and/or the second precursor 8, and forming the material layer 4 onto the substrate 2. It is contemplated that deposition of the material layer 4 onto the substrate 2 be accomplished using a CVD technique. For example, deposition of the material layer 4 may be accomplished using an ALD technique or a PEALD technique.

As has been explained above, heating substrates to a desired deposition temperature can, in some deposition operations, cause cracking within the ceramic material forming the substrate support structure. For example, material layer deposition temperatures less than 350° C., or less than 300° C., or even less than 250° C. can cause some ceramic materials to crack, for example, due to thermal stress associated with heating the ceramic material to the material layer deposition temperature, heating the ceramic material relatively quickly to the material layer deposition temperature, and/or cooling the ceramic material relatively quickly from the material layer deposition temperature. Thermal stress within the ceramic material forming the substrate support structure associated with ramping the substrate to a desired deposition temperature can, in some substrate support structures, also cause cracking within the ceramic material forming the substrate. And sequentially heating substrates to a desired material layer deposition temperature can cause cracking of the ceramic material forming the substrate support structure can, in some substrate support structures, cause cracking within the ceramic material forming the substrate support structure. To limit (or eliminate) cracking of the substrate support structure 100 during the deposition of the material layer 4 onto the substrate 2 while supported within the chamber body 36 allow for employment of deposition temperatures between about 250° C. and about 850° C., or between about between about 450° C. and about 850° C., or even between abut between about 650° C. and about 850° C., the ceramic composite 114 is provided.

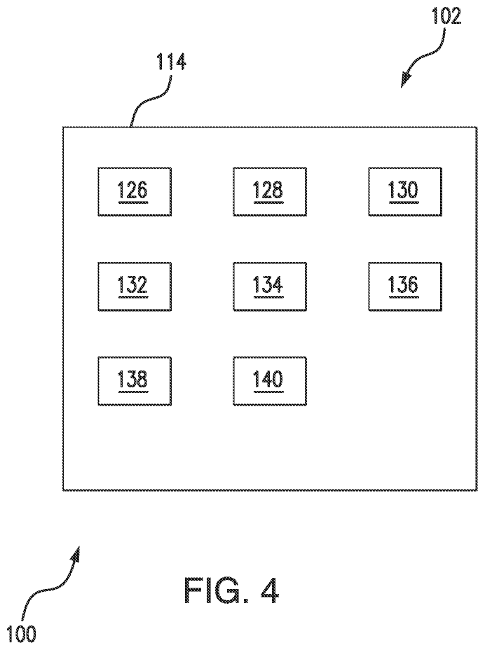

With reference to FIG. 4, the substrate support structure body 102 including the ceramic composite 114 is shown. The ceramic composite 114 includes two or more constituents selected from a group including (a) an aluminum nitride (AlN) constituent 126, (b) an aluminum oxynitride (Al_{2.81}O_{3.56}N_{0.44}, AlON) constituent 128, (c) an alpha-alumina (α-Al₂O₃) constituent 130, (d) a yttrium alumina garnet (Y₃Al₅O₁₂, YAG) constituent 132, (e) a yttrium alumina monoclinic (Y₄Al₂O₉, YAM) constituent 134, (f) a yttrium alumina perovskite (YAlO₃, YAP) constituent 136, (g) a yttrium oxide (Y₂O₃) constituent 138, and (i) a titanium dioxide (TiO2) constituent 140. For example, the ceramic composite 114 may include only two of the AlN constituent 126, the AlON constituent 128, the alpha-alumina constituent 130, the YAG constituent 132, the YAM constituent 134, the YAP constituent 136, and the Y₂O₃ constituent 138. In certain examples, the ceramic composite 114 may include only two of the AlN constituent 126, the AlON constituent 128, the alpha-alumina constituent 130, the YAG constituent 132, the YAM constituent 134, the YAP constituent 136, and the Y₂O₃ constituent 138. Applicant has determined that, by forming the ceramic composite 114 from an aluminum-oxynitride, alumina, and yttrium oxide ceramic system, that the substrate support structure 100 may be reliably employed at deposition temperatures greater than that possible with aluminum-oxynitride compositions having different constituents.

In certain examples, the ceramic composite 114 may consist essentially of the two or more constituents selected from the group including the AlN constituent 126, the AlON constituent 128, the alpha-alumina constituent 130, the YAG constituent 132, the YAM constituent 132, the YAP constituent 134, and the Y₂O₃ constituent 138. In accordance with certain examples, the ceramic composite 114 may consist of the two or more constituents selected from the group including the AlN constituent 126, the AlON constituent 128, the alpha-alumina constituent 130, the YAG constituent 132, the YAM constituent 134, the YAP constituent 136, and the Y₂O₃ constituent 138.

It is contemplated that the ceramic composite 114 may have electrical and mechanical properties that allow the substrate support structure 100 to heat the substrate 2 (shown in FIG. 2) to temperatures between about 250° C. and about 850° C., or between about between about 450° C. and about 850° C., or even between abut between about 650° C. and about 850° C. without exhibiting cracking, improving reliability of the semiconductor processing system 10 (shown in FIG. 1). The electrical properties may be such that, at temperatures between about 250° C. and about 850° C., or between about between about 450° C. and about 850° C., or even between abut between about 650° C. and about 850° C., the substrate support structure 100 may electrostatically fix the substrate 2 to the substrate support structure 100. For example, the ceramic composite 114 may have volume resistivity such that leakage current of the bulk material forming the substrate support structure 100 is between about 0.16 mA and about 0.08 mA, or between about 0.12 mA and about 0.08 mA, or even between about 0.10 mA and about 0.08 mA at 1000° C. The ceramic composite 114 may have a leakage current of about 0.9 mA at 1000° C. As will be appreciated by those of skill in the art in view of the present disclosure, leakage current within these ranges allow the substrate support structure 100 to provide electrostatic chucking at relatively high temperature, e.g., between about 250° C. and about 850° C.

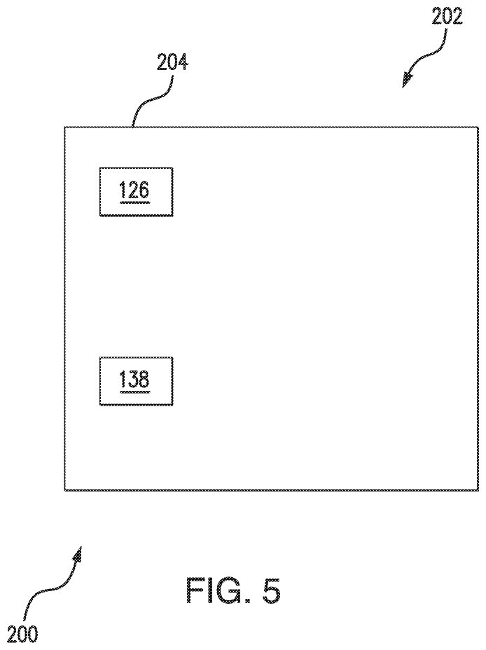

With reference to FIG. 5, a substrate support structure 200 is shown. The substrate support structure 200 is similar to the substrate support structure 100 (shown in FIG. 1) and additionally includes a substrate support structure body 202 formed from a ceramic composite 204. The ceramic composite 204 includes the AlN constituent 126 and the Y₂O₃ constituent 138. In certain examples, the ceramic composite 204 may consist essentially of the AlN constituent 126 and the Y₂O₃ constituent 138. In accordance with certain examples, the ceramic composite 204 may consist of the AlN constituent 126 and the Y₂O₃ constituent 138. In certain examples, the ceramic composite 204 may have more of the AlN constituent 126, e.g., by mass fraction and/or volume), than the Y₂O₃ constituent 138. For example, the AlN constituent 126 may form between about 35% and about 65% of the ceramic composite 204. In accordance with certain examples, the ceramic composite 204 may have more of the Y₂O₃ constituent 138 than the AlN constituent 126. For example, the Y₂O₃ constituent 138 may form between about 35% and about 65% of the ceramic composite 204.

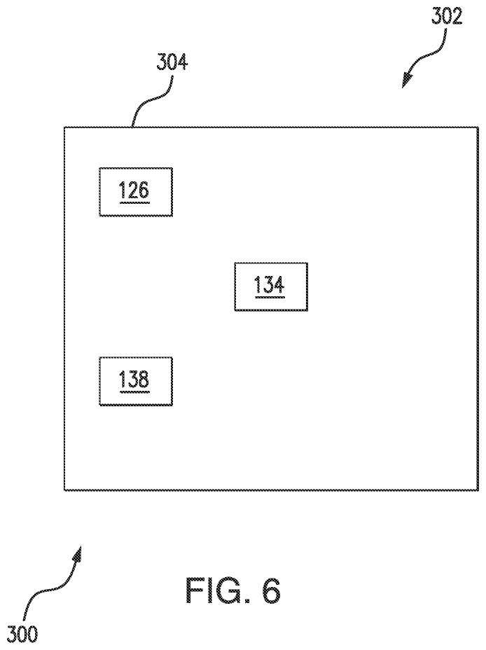

With reference to FIG. 6, a substrate support structure 300 is shown. The substrate support structure 300 is similar to the substrate support structure 100 (shown in FIG. 1) and additionally includes a substrate support structure body 302 formed from a ceramic composite 304. The ceramic composite 304 includes the AlN constituent 126, the YAM constituent 134, and the Y₂O₃ constituent 138. In certain examples the ceramic composite 304 may consist essentially of the AlN constituent 126, the YAM constituent 134, and the Y₂O₃ constituent 138. In accordance with certain examples, the ceramic composite 304 may consist of the AlN constituent 126, the YAM constituent 134, and the Y₂O₃ constituent 138. It is contemplated that, in accordance with certain examples, the ceramic composite 304 may have more (e.g., by mass fraction and/or volume) of the AlN constituent 126 than either (or both) the YAM constituent 134 and the Y₂O₃ constituent 138. It is also contemplated that, in accordance with certain examples, the ceramic composite 304 may have more of the Y₂O₃ constituent 138 than the AlN constituent 126 and/or the YAM constituent 134. For example, the AlN constituent 126 may form between about 15% and about 40% of the ceramic composite 304, the YAM constituent 134 may from between about 30% and about 50% of the ceramic composite 304, and the Y₂O₃ constituent 138 may form between about 30% and about 55% of the ceramic composite 304.

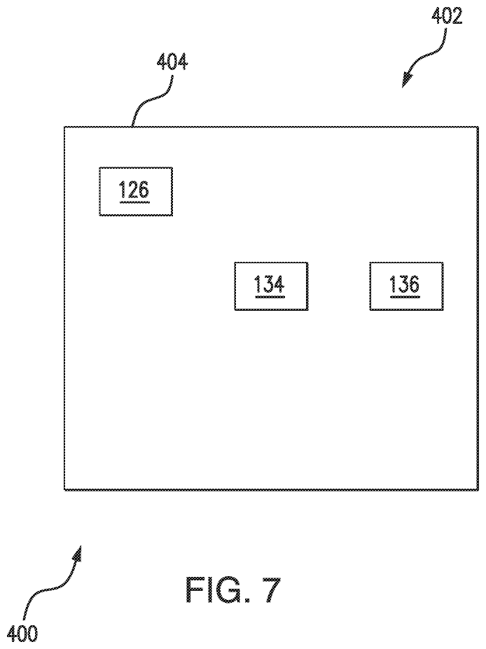

With reference to FIG. 7, a substrate support structure 400 is shown. The substrate support structure 400 is similar to the substrate support structure 100 (shown in FIG. 1) and additionally includes a substrate support structure body 402 formed from a ceramic composite 404. The ceramic composite 404 includes the AlN constituent 126, the YAM constituent 134, and the YAP constituent 136. In certain examples the ceramic composite 404 may consist essentially of the AlN constituent 126, the YAM constituent 134, and the YAP constituent 136. In accordance with certain examples, the ceramic composite 404 may consist of the AlN constituent 126, the YAM constituent 134, and the YAP constituent 136. It is contemplated that, in certain examples, the ceramic composite 404 may have more (e.g., by mass fraction and/or volume) of the YAP constituent 136 than the AlN constituent 126 and/or the YAM constituent 134. It is also contemplated that the ceramic composition may have more of the YAM constituent 134 than the YAP constituent 136 and/or the AlN constituent 126. For example, the AlN constituent 126 may form between about 15% and about 30% of the ceramic composite 404, the YAM constituent 134 may form between about 15% and about 45% of the ceramic composite 404, and the YAP constituent 136 may form between about 30% and about 70% of the ceramic composite 404.

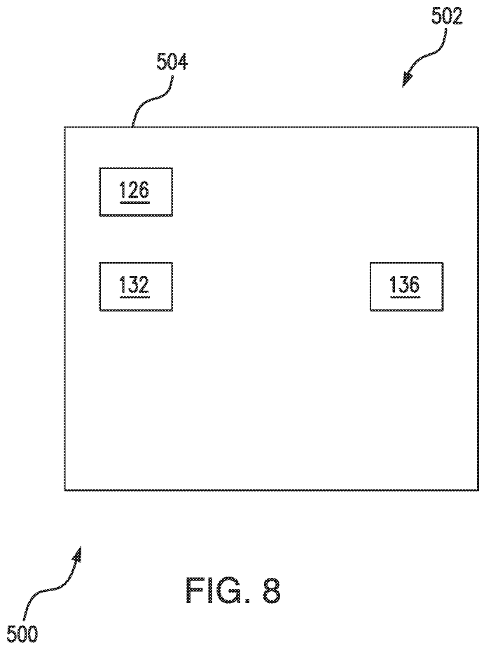

With reference to FIG. 8, a substrate support structure 500 is shown. The substrate support structure 500 is similar to the substrate support structure 100 (shown in FIG. 1) and additionally includes a substrate support structure body 502 formed from a ceramic composite 504. The ceramic composite 504 includes the AlN constituent 126, the YAG constituent 132, and the YAP constituent 136. In certain examples the ceramic composite 504 may consist essentially of the AlN constituent 126, the YAG constituent 132, and the YAP constituent 136. In accordance with certain examples, the ceramic composite 504 may consist of the AlN constituent 126, the YAG constituent 132, and the YAP constituent 136. It is contemplated that, in certain examples, the ceramic composite 504 may have more (e.g., by mass fraction and/or volume) of the YAG constituent 132 than the AlN constituent 126 and/or the YAM constituent 134. It is also contemplated that the ceramic composition may have more of the YAP constituent 136 than the AlN constituent 126. In these respects the AlN constituent 126 may form between about 15% and about 35% of the ceramic composite 504, the YAG constituent 132 may form between about 40% and about 55% of the ceramic composite 504, and the YAP constituent 136 may form between about 15% and about 45% of the ceramic composite 504.

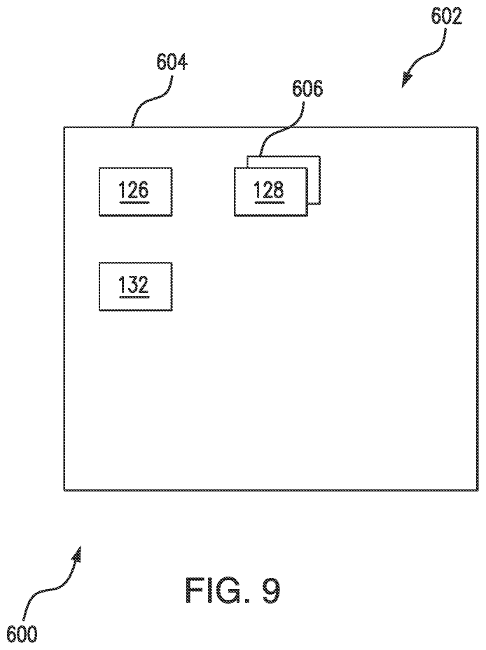

With reference to FIG. 9, a substrate support structure 600 is shown. The substrate support structure 600 is similar to the substrate support structure 100 (shown in FIG. 1) and additionally includes a substrate support structure body 602 formed from a ceramic composite 604. The ceramic composite 604 includes the AlN constituent 126, the AlON constituent 128, and the YAG constituent 132. In certain examples the ceramic composite 604 may consist essentially of the AlN constituent 126, the AlON constituent 128, and the YAG constituent 132. In accordance with certain examples, the ceramic composite 604 may consist of the AlN constituent 126, the AlON constituent 128, and the YAG constituent 132. It is contemplated that, in certain examples, the AlON constituent 128 may have a spinel crystalline structure 606. It is also contemplated that, in accordance with certain examples, the ceramic composite 604 may have more (e.g., by mass fraction and/or volume) of the AlON constituent 128 than the AlN constituent 126 and/or the YAG constituent 132. For example, the AlN constituent 126 may form between about 25% and about 30% of the ceramic composite 604, the AlON constituent 128 may form between about 55% and about 60% of the ceramic composite 604, and the YAG constituent 132 may form between about 10% and about 15% of the ceramic composite 604.

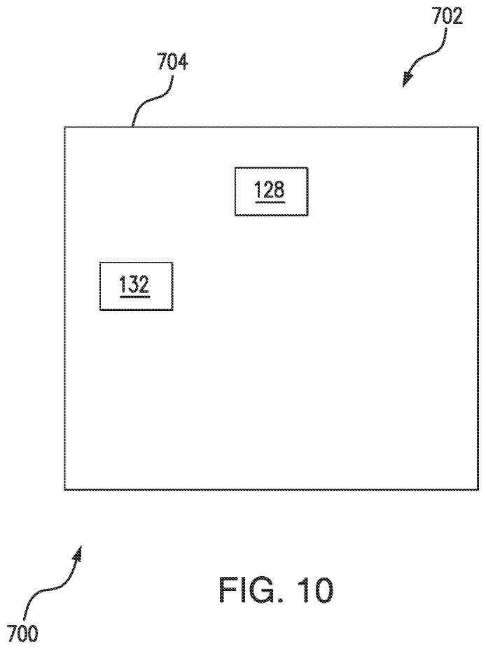

With reference to FIG. 10, a substrate support structure 700 is shown. The substrate support structure 700 is similar to the substrate support structure 100 (shown in FIG. 1) and additionally includes a substrate support structure body 702 formed from a ceramic composite 704. The ceramic composite 704 includes the AlON constituent 128 and the YAG constituent 132. In certain examples, the ceramic composite 704 may consist essentially of the AlON constituent 128 and the YAG constituent 132. In accordance with certain examples, the ceramic composite 704 may consist of the AlON constituent 128 and the YAG constituent 132. In certain examples, the ceramic composite 704 may have more (e.g., by mass fraction and/or volume) of the AlON constituent 128 than the YAG constituent 132. For example, the AlON constituent 128 may form between about 55% and about 95% of the ceramic composite 704 and the YAG constituent 132 may form between about 5% and about 40% of the ceramic composite 704.

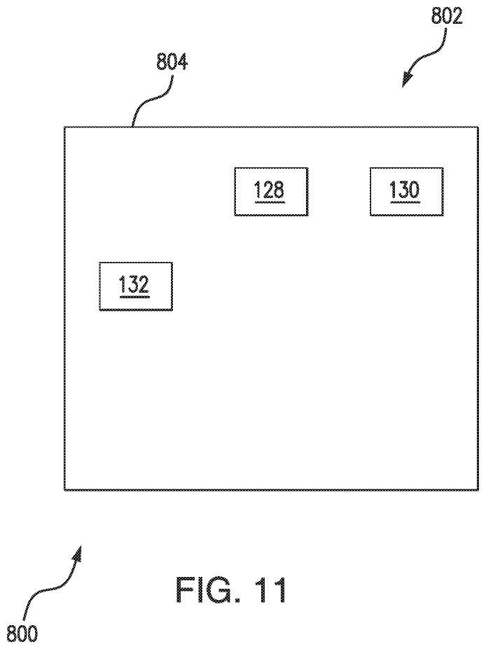

With reference to FIG. 11, a substrate support structure 800 is shown. The substrate support structure 800 is similar to the substrate support structure 100 (shown in FIG. 1) and additionally includes a substrate support structure body 802 formed from a ceramic composite 804. The ceramic composite 804 includes the AlON constituent 128, the alpha-alumina constituent 130, and the YAG constituent 132. In certain examples, the ceramic composite 804 may consist essentially of the AlON constituent 128, the alpha-alumina constituent 130, and the YAG constituent 132. In accordance with certain examples, the ceramic composite 804 may consist of the AlON constituent 128, the alpha-alumina constituent 130, and the YAG constituent 132. It is contemplated that, in certain examples, the AlON constituent 128 may form more (e.g., by mass fraction and/or volume) of the ceramic composite 804 than the alpha-alumina constituent 130. It is also contemplated that, in accordance with certain examples, the YAG constituent 132 may form more of the ceramic composite 804 than the AlON constituent 128 and/or the alpha-alumina constituent 130. In these respects the AlON constituent 128 may form between about 30% and about 40% of the ceramic composite 804, the alpha-alumina may form between about 25% and about 30% of the ceramic composite 804, and the YAG constituent 132 may form between about 35% and about 40% of the ceramic composite 804.

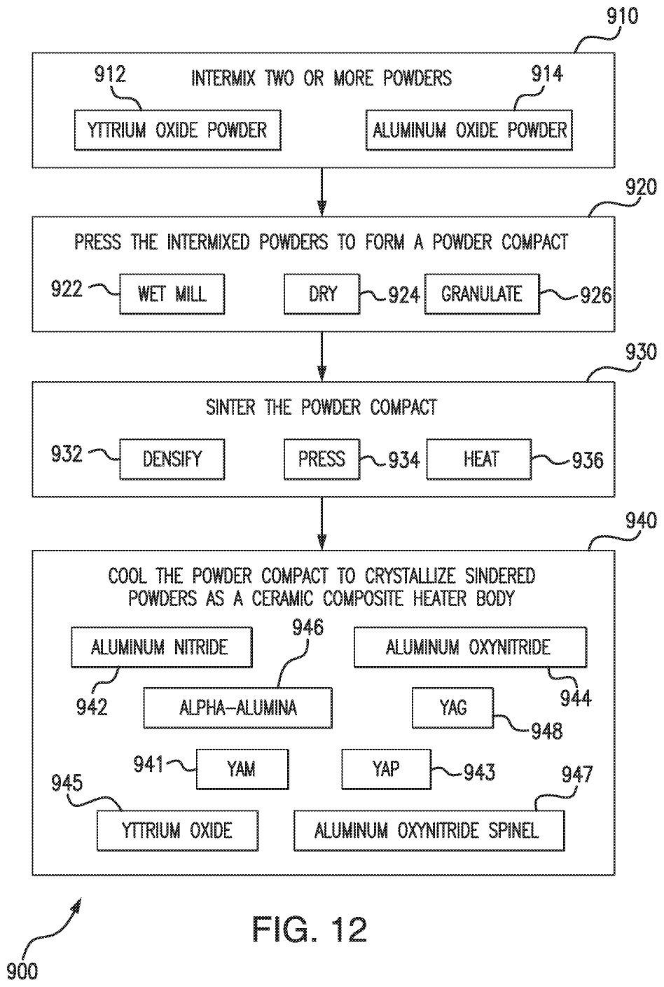

With reference to FIG. 12, a method 900 of making a substrate support structure, e.g., the substrate support structure 100 (shown in FIG. 1), is shown. The method 900 includes intermixing a plurality of powders and pressing the intermixed powders to form a powder compact, as shown with box 910 and box 920. Once pressed, the powder compact is sintered at a predetermined pressure and a predetermined temperature, as shown with box 930. Once sintered, the powder compact is thereafter cooled at a predetermined cooling rate to form a substrate support structure body, e.g., the substrate support structure body 102 (shown in FIG. 3), with a bulk material including a ceramic composite, e.g., the ceramic composite 114 (shown in FIG. 3), as shown with box 940. It is contemplated that predetermined pressure and predetermined temperature of the sintering operation, as well as the predetermined cooling conditions, be selected to impart predetermined crystalline structures to constituents, e.g., ceramic materials, forming the substrate support structure body.

Intermixing 910 the powders may include mixing an alpha-aluminum oxide (Al₂O₃) powder with an yttrium oxide (Y₂O₃) powder and an aluminum nitride (AlN) powder, as shown with box 912 and box 914. The powders may be intermixed such that the resulting mixture includes between about 0.02 Mol % and about 85 Mol % aluminum oxide (Al₂O₃), between about 10 Mol % and about 65 Mol % yttrium oxide (Y₂O₃), and/or between about 5 Mol % and about 65 Mol % aluminum nitride (AlN). In certain examples, the AlN powder included in the mixture may be about 99.90% pure, the alpha-alumina powder included in the mixture about 99.99% pure, and the yttrium oxide power included in the mixture about 99.90% pure. In accordance with certain examples, one or more of the intermixed powders may have particles having sized such that D₅₀ is less than about 2 microns, for example particles of each powder includes in the AlN-A₂O₃—Y₂O₃ system sized such that D₅₀ is less than 2 microns.

Forming 920 the powder compact may include intermixing the powders with isopropanol. The intermixed powder may be milled, such using a planetary ball mill, as shown with box 922. The intermixed powders may be milled in the planetary ball mill at a predetermined rate for a predetermined interval of time, for example, at a speed of about 200 rotations per minute for about two (2) hours. The intermixed powders may be dried subsequent to milling, such as using a rotary evaporator, as shown with box 924. The intermixed powders may be granulated, such as by passing the dried powder through a 325-micron sieve, and the granulated intermixed powders thereafter pressed to form the powder compact, as shown with box 926. As will be appreciated by those of skill in the art, milling the intermixed powders prior to granulating provides uniformity to the distribution of the two or more powders within the pressed compact to ensure that the desired constituents from within the sintered compact with predetermined compositions and/or crystalline structure.

Sintering 930 the powder compact may include densifying the powder compact, for example, using a spark plasma sintering technique, as shown with box 932. In this respect the powder compact may be plasma sintered for a predetermined sintering period. The predetermined sintering period may be between about 2 minutes and about 10 minutes, or between about 3 minutes and about 8 minutes, or even between about 4 minutes and about 6 minutes. The plasma compact may be plasma sintered for about 5 minutes. The powder compact may be sintered at a predetermined sintering pressure. The predetermined sintering pressure may be between about 20 MPa and about 100 MPa, or between about 30 MPa and about 80 MPa, or between about 40 MPa and about 60 MPa, or at about 50 MPa, as shown with box 934. The powder compact may be sintered at a predetermined sintering temperature. The predetermined sintering temperature may be between about 1500° C. and about 1750° C., or is between about 1525° C. and about 1725° C., or is between about 1550° C. and about 1700° C., as shown with box 934. Sintering the powder compact may include heating the powder compact at rate that is between about 50° K/min and about 150° K/min, or between about 70° K/min and about 130° K/min, or is between about 90° K/min and about 110° K/min, or is about 100° K/min.

Cooling 940 the sintered powder compact includes cooling the sintered powder compact such that the ceramic powder compact including two or more constituents selected from a group including (a) an aluminum nitride (AlN) constituent, (b) an aluminum oxynitride (Al_{2.81}O_{3.56}N_{0.44}, AlON) constituent, (c) an alpha-alumina (α-Al₂O₃) constituent, (d) a yttrium alumina garnet (Y₃Al₅O₁₂, YAG) constituent, (e) a yttrium alumina monoclinic (Y₄Al₂O₉, YAM) constituent, (f) a yttrium alumina perovskite (YAlO₃, YAP) constituent, and (g) a yttrium oxide (Y₂O₃) constituent, as shown with boxes 941-945. In certain examples, cooling the sintered powder compact may include supercooling the sintered powder compact such that one or more of the constituents form relatively large crystals. In accordance with certain examples, a liquid phase of one or more of the constituents of the ceramic composites may be limited (or completely absent) from the ceramic composite as a result of the cooling.

Without wishing to be bound by theory, applicant has determined that, by sintering compacts of AlN—Al₂O₃—Y₂O₃ powders at temperatures above 1550° C., ceramic composites may be formed having predetermined compounds and/or compound phases providing mechanical properties required for electrostatic chucks and substrate support structures and resistance to crack formation and crack growth at high temperatures. Specifically, the ceramic composite 114 (shown in FIG. 3) may be formed including alumina oxynitride (Al_{2.81}O_{3.56}N_{0.44}, AlON) (γ-spinel) and yttrium alumina garnet (Y₃Al₅O₁₂, YAG) in proportions where the resulting ceramic composite has hardness and optical properties similar to AlON and thermal properties more closely corresponding to YAG.

In one example, a powder compact including 56% Al₂O₃, 14% Y₂O₃, and 30% AlN was formed using AlN (99.90%), α-Al₂O₃ (99.99%), and Y₂O₃ (99.90%) powders. The powders had particle sizes of D₅₀<2 um, were intermixed with one another and isopropanol in a planetary ball mill at 200 rpm for two hours, dried in a rotary evaporator, and granulated through a 325-micron sieve. A powder compact was formed from the granulated powders and densified using a spark plasma sintering technique for 5 minutes at 1600° C. while under vacuum (e.g., about 50 MPa) to form a ceramic substrate support structure. XRD (Rietveld) inspection of the resulting ceramic substrate support structure showed a ceramic composite having 28.10% aluminum nitride (AlN), 57.52% aluminum oxynitride (Al_{2.81}O_{3.56}N_{0.44}, AlON), and 14.38% yttrium alumina garnet (Y₃Al₅O₁₂, YAG).

In another example, a powder compact including 63% Al₂O₃, 14.5% Y₂O₃, and 22.50% AlN was formed using AlN (99.90%), α-Al₂O₃ (99.99%), and Y₂O₃ (99.90%) powders. The powders had particle sizes of D₅₀<2 um, were intermixed with one another and isopropanol in a planetary ball mill at 200 rpm for two hours, dried in a rotary evaporator, and granulated through a 325-micron sieve. A powder compact was formed from the granulated powders and densified using a spark plasma sintering technique for 5 minutes at 1700° C. while under vacuum (50 MPa) to form a ceramic substrate support structure. XRD (Rietveld) inspection of the resulting ceramic substrate support structure showed a ceramic composite having 61.40% aluminum oxynitride (Al_{2.81}O_{3.56}N_{0.44}, AlON) and 38.60% yttrium alumina garnet (Y₃Al₅O₁₂, YAG).

In a further example, a powder compact including 61.50% Al₂O₃, 11.00% Y₂O₃, and 27.50% AlN was formed using AlN (99.90%), α-Al₂O₃ (99.99%), and Y₂O₃ (99.90%) powders. The powders had particle sizes of D₅₀<2 um, were intermixed with one another and isopropanol in a planetary ball mill at 200 rpm for two hours, dried in a rotary evaporator, and granulated through a 325-micron sieve. A powder compact was formed from the granulated powders and densified using a spark plasma sintering technique for 5 minutes at 1700° C. while under vacuum (50 MPa) to form a ceramic substrate support structure. XRD (Rietveld) inspection of the resulting ceramic substrate support structure showed a ceramic composite having 74.21% aluminum oxynitride (Al_{2.81}O_{3.56}N_{0.44}, AlON) and 25.79% yttrium alumina garnet (Y₃Al₅O₁₂, YAG).

In yet another example, a powder compact including 70.00% Al₂O₃, 15.60% Y₂O₃, and 14.40% AlN was formed using AlN (99.90%), α-Al₂O₃ (99.99%), and Y₂O₃ (99.90%) powders. The powders had particle sizes of D₅₀<2 um, were intermixed with one another and isopropanol in a planetary ball mill at 200 rpm for two hours, dried in a rotary evaporator, and granulated through a 325-micron sieve. A powder compact was formed from the granulated powders and densified using a spark plasma sintering technique for 5 minutes at 1700° C. while under vacuum (50 MPa) to form a ceramic substrate support structure. XRD (Rietveld) inspection of the resulting ceramic substrate support structure showed a ceramic composite having 92.30% aluminum oxynitride (Al_{2.81}O_{3.56}N_{0.44}, AlON) and 7.70% yttrium alumina garnet (Y₃Al₅O₁₂, YAG).

In a further example, a powder compact including 79.00% Al₂O₃, 14.00% Y₂O₃, and 7.00% AlN was formed using AlN (99.90%), α-Al₂O₃ (99.99%), and Y₂O₃ (99.90%) powders. The powders had particle sizes of D₅₀<2 um, were intermixed with one another and isopropanol in a planetary ball mill at 200 rpm for two hours, dried in a rotary evaporator, and granulated through a 325-micron sieve. A powder compact was formed from the granulated powders and densified using a spark plasma sintering technique for 5 minutes at 1600° C. while under vacuum (e.g., about 50 MPa) to form a ceramic substrate support structure. XRD (Rietveld) inspection of the resulting ceramic substrate support structure showed a ceramic composite having 35.00% aluminum oxynitride (Al_{2.81}O_{3.56}N_{0.44}, AlON), 26.00% alpha alumina (α-Al₂O₃), and 39.00% yttrium alumina garnet (Y₃Al₅O₁₂, YAG).

Examples of AlN—Al₂O₃—Y₂O₃ powder mixtures, powder compact sintering temperatures, and the associated resultant ceramic composite following sintering are provided in Table 1.

TABLE 1

| | | Initial Powder | | | Phases Identified by XRD (Rietveld) after SPS | | | | | | |
|---|---|---|---|---|---|---|---|---|---|---|---|
| | T | Composition (Mol %) | | | | γ- | α- | | | | |
| Sample | (° C.) | Al₂O₃ | Y₂O₃ | AlN | AlN | spinel | Al₂O₃ | YAG | YAM | YAP | Y₂O₃ |
| A | 1550 | 0.024 | 39.98 | 59.99 | 59.55 | | | | | | 40.45 |
| B | 1550 | 0.023 | 59.99 | 39.99 | 39.75 | | | | | | 60.25 |
| C | 1550 | 13.02 | 39.99 | 46.99 | 39.83 | | | | 26.50 | | 33.67 |
| D | 1550 | 11.01 | 59.99 | 38.00 | 35.01 | | | | 24.11 | | 40.88 |
| F | 1550 | 12.50 | 54.5 | 33.00 | 30.01 | | | | 23.19 | | 46.80 |
| G | 1550 | 14.00 | 57.80 | 28.20 | 25.23 | | | | 21.21 | | 53.56 |
| H | 1550 | 29.75 | 35.25 | 35.00 | 28.11 | | | | 41.00 | 30.89 | |
| I | 1550 | 39.50 | 43.25 | 17.25 | 18.21 | | | | 15.00 | 66.79 | |
| J | 1550 | 37.00 | 27.50 | 35.50 | 33.00 | | | 50.00 | | 20.00 | |
| K | 1550 | 42.00 | 31.00 | 27.00 | 21.00 | | | 47.40 | | 31.60 | |
| L | 1550 | 45.00 | 34.20 | 20.80 | 20.00 | | | 48.00 | | 32.00 | |
| M | 1550 | 45.00 | 37.00 | 18.00 | 18.00 | | | 42.00 | | 40.00 | |
| N | 1600 | 56.00 | 14.00 | 30.00 | 28.10 | 57.52 | | 14.38 | | | |
| O | 1700 | 63.00 | 14.50 | 22.50 | | 61.40 | | 38.60 | | | |
| P | 1700 | 61.50 | 11.00 | 27.50 | | 74.21 | | 25.79 | | | |
| Q | 1700 | 70.00 | 15.60 | 14.40 | | 92.30 | | 7.70 | | | |
| R | 1600 | 79.00 | 14.00 | 7.00 | | 35.00 | 26.00 | 39.00 | | | |

Advantageously, ceramic composites formed using the foregoing composition N show mechanical resistance in the range of 300-450 MPa, thermal conductivity in the range of 25-80 W/m°, and volume resistivity in the range of 10¹⁰-10¹¹ Ohm-cm within a temperature range of 550-650 degrees Celsius. Volume resistivity within this range at temperatures between 550 degrees Celsius and 650 degrees Celsius is unexpectedly good, and indicates that electrostatic chucking is possible at temperatures greater previously contemplated while having retaining mechanical resistance and thermal conductivity suitable of material layer deposition at higher temperatures than previously possible.

Although the examples provided above are directed to ceramic composites including aluminum oxynitride (Al_{2.81}O_{3.56}N_{0.44}, AlON) and yttrium alumina garnet (Y₃Al₅O₁₂, YAG), it is to be understood and appreciated that other ceramic composites having reduced susceptibility to nano-micro crack formation and cracking during thermal cycling at temperatures greater than 450° C. may also be fabricated using methods described herein. For example, ceramic composites including two or more of aluminum nitride (AlN), yttrium alumina garnet (Y₃Al₅O₁₂, YAG), yttrium alumina monoclinic (Y₄Al₂O₉, YAM), and yttrium oxide (Y₂O₃) having excellent tolerance for contact with chemistries employed in the plasma-enhanced chemical vapor deposition of material layers may also be formed using the methods described herein. It will be apparent to the skilled person that the ceramic composites described herein can be used to form any substrate support structure used in semiconductor manufacturing that comes into contact with the chemistries employed in plasma-enhanced chemical vapor deposition of material layers, such as but not limited to chamber and chamber components, wafer susceptor or chuck, showerhead, liners, rings, nozzles, baffles and fasteners, and wafer transport components.

While various ceramic composites and methods are described, it is to be understood that this invention is not limited to the particular molecules, ceramic composites, designs, methodologies or protocols described, as these may vary. It is also to be understood that the terminology used in the description is for the purpose of describing the particular versions or embodiments only, and is not intended to limit the scope of the present invention which will be limited only by the appended claims.

It must also be noted that as used herein and in the appended claims, the singular forms “a”, “an”, and “the” include plural reference unless the context clearly dictates otherwise. Thus, for example, reference to a “phase” is a reference to one or more constituent compound and/or crystalline structure of the compound of a ceramic material and equivalents thereof known to those skilled in the art, and so forth. As used herein, the term “high temperature” refers to temperatures greater than 300° C., or greater than 400° C., or even greater than 500° C. Unless defined otherwise, all technical and scientific terms used herein have the same meanings as commonly understood by one of ordinary skill in the art. Methods and materials similar or equivalent to those described herein can be used in the practice or testing of embodiments of the present invention. All publications mentioned herein are incorporated by reference in their entirety. Nothing herein is to be construed as an admission that the invention is not entitled to antedate such disclosure by virtue of prior invention. “Optional” or “optionally” means that the subsequently described event or circumstance may or may not occur, and that the description includes instances where the event occurs and instances where it does not. All numeric values herein can be modified by the term “about,” whether or not explicitly indicated. The term “about” generally refers to a range of numbers that one of skill in the art would consider equivalent to the recited value (i.e., having the same function or result). In some embodiments the term “about” refers to +/−0.10% of the stated value, in other embodiments the term “about” refers to +/−0.20% of the stated value. While ceramic composites and methods are described in terms of “comprising” various components or steps (interpreted as meaning “including, but not limited to”), the ceramic composites and methods can also “consist essentially of” or “consist of” the various components and steps, such terminology should be interpreted as defining essentially closed or closed member groups.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that features and/or elements depicted herein are illustrated with particular dimensions and/or orientations relative to one another for purposes of simplicity and ease of understanding, and that the actual dimensions and/or orientations may differ substantially from that illustrated herein.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate support structure for semiconductor processing system, comprising:
a substrate support structure body formed from a ceramic composite, the body having:
a first surface;
a second surface spaced apart from the first surface;
a periphery spanning the first surface and the second surface of the substrate support structure body, wherein the first surface, the second surface and the periphery of the substrate support structure body are defined by the ceramic composite; and
wherein the ceramic composite comprises two or more constituents selected from a group comprising (a) an aluminum nitride (AlN) constituent, (b) an aluminum oxynitride (Al_{2.81}O_{3.56}N_{0.44}, AlON) constituents, (c) an alpha-alumina (α-Al₂O₃) constituent, (d) a yttrium alumina garnet (Y₃Al₅O₁₂, YAG) constituent, (e) a yttrium alumina monoclinic (Y₄Al₂O₉, YAM) constituent, (f) a yttrium alumina perovskite (YAlO₃, YAP) constituent, and (g) a yttrium oxide (Y₂O₃) constituent.

2. The substrate support structure of claim 1, wherein the ceramic composite consists essentially of the aluminum nitride (AlN) constituent and the yttrium oxide (Y₂O₃) constituent.

3. The substrate support structure of claim 2, wherein the ceramic composite includes more of the aluminum nitride (AlN) constituent than the yttrium oxide (Y₂O₃) constituent.

4. The substrate support structure of claim 2, wherein the ceramic composite includes between about 35% and about 65% the aluminum nitride (AlN) constituent.

5. The substrate support structure of claim 1, wherein the ceramic composite consists essentially of the aluminum nitride (AlN) constituent, an yttrium alumina monoclinic (Y₄Al₂O₉, YAM) constituent, and an yttrium oxide (Y₂O₃) constituent.

6. The substrate support structure of claim 5, wherein the ceramic composite includes more the aluminum nitride (AlN) constituent than the yttrium alumina monoclinic (Y₄Al₂O₉, YAM) constituent.

7. The substrate support structure of claim 5, wherein the ceramic composite includes between about 25% and about 40% of the aluminum nitride (AlN) constituent, between about 20% and about 30% of the yttrium alumina monoclinic (Y₄Al₂O₉, YAM) constituent, and between about 30% and about 55% of the yttrium oxide (Y₂O₃) constituent.

8. The substrate support structure of claim 1, wherein the ceramic composite consists essentially of the aluminum nitride (AlN) constituent, the yttrium alumina monoclinic (Y₄Al₂O₉, YAM) constituent, and the yttrium alumina perovskite (YAlO₃, YAP) constituent.

9. The substrate support structure of claim 8, wherein the ceramic composite includes more of the yttrium alumina perovskite (YAlO₃, YAP) constituent than the aluminum nitride (AlN) constituent.

10. The substrate support structure of claim 8, wherein the ceramic composite includes between about 15% and about 30% of the aluminum nitride (AlN) constituent, between about 15% and about 45% of the yttrium alumina monoclinic (Y₄Al₂O₉, YAM) constituent, and between about 30% and about 70% of the yttrium alumina perovskite (YAlO₃, YAP) constituent.

11. The substrate support structure of claim 1, wherein the ceramic composite consists essentially of the aluminum nitride (AlN) constituent, the yttrium alumina garnet (Y₃Al₅O₁₂, YAG) constituent, and the yttrium alumina perovskite (YAlO₃, YAP) constituent.

12. The substrate support structure of claim 11, wherein the ceramic composite includes more of the yttrium alumina garnet (Y₃Al₅O₁₂, YAG) constituent than the aluminum nitride (AlN) constituent, wherein the ceramic composite includes more of the yttrium alumina garnet (Y₃Al₅O₁₂, YAG) constituent than the yttrium alumina perovskite (YAlO₃, YAP) constituent.

13. The substrate support structure of claim 11, wherein the ceramic composite includes between about 15% and about 35% the aluminum nitride (AlN) constituent, between about 40% and about 50% of the yttrium alumina garnet (Y₃Al₅O₁₂, YAG) constituent, and between about 20% and about 40% of the yttrium alumina perovskite (YAlO₃, YAP) constituent.

14. The substrate support structure of claim 1, wherein the ceramic composite consists essentially of the aluminum nitride (AlN) constituent, the aluminum oxynitride (Al_{2.81}O_{3.56}N_{0.44}, AlON) constituent, and the yttrium alumina garnet (Y₃Al₅O₁₂, YAG) constituent.

15. The substrate support structure of claim 14, wherein the ceramic composite includes more of the aluminum oxynitride (Al_{2.81}O_{3.56}N_{0.44}, AlON) constituent than the aluminum nitride (AlN) constituent and the yttrium alumina garnet (Y₃Al₅O₁₂, YAG) constituent.

16. The substrate support structure of claim 14, wherein the ceramic composite includes between about 25% and about 30% of the aluminum nitride (AlN) constituent, between about 55% and about 60% of the aluminum oxynitride (Al_{2.81}O_{3.56}N_{0.44}, AlON) constituent, and between about 10% and about 20% of the yttrium alumina garnet (Y₃Al₅O₁₂, YAG) constituent.

17. The substrate support structure of claim 1, wherein the ceramic composite consists essentially of the aluminum oxynitride (Al_{2.81}O_{3.56}N_{0.44}, AlON) constituent and the yttrium alumina garnet (Y₃Al₅O₁₂, YAG) constituent.

18. The substrate support structure of claim 17, wherein the ceramic composite includes more the aluminum oxynitride (Al_{2.81}O_{3.56}N_{0.44}, AlON) constituent than the yttrium alumina garnet (Y₃Al₅O₁₂, YAG) constituent.

19. The substrate support structure of claim 17, wherein the ceramic composite includes between about 60% and about 95% of the aluminum oxynitride (Al_{2.81}O_{3.56}N_{0.44}, AlON) constituent and between about 5% and about 40% of the yttrium alumina garnet (Y₃Al₅O₁₂, YAG) constituent.

20. The substrate support structure of claim 1, wherein the ceramic composite consists essentially of the aluminum oxynitride (Al_{2.81}O_{3.56}N_{0.44}, AlON) constituent, the alpha-alumina (alpha-alumina (α-Al₂O₃) constituent, and the yttrium alumina garnet (Y₃Al₅O₁₂, YAG) constituent.

21. The substrate support structure of claim 1, further comprising at least one of a heater element, a coolant circuit, and a temperature sensor embedded within the ceramic composite.

22. A semiconductor processing system, comprising:
a gas delivery system;
a reaction chamber connected to the gas delivery system; and
a showerhead and a substrate support structure as recited in claim 1 supported within the reaction chamber, wherein the showerhead fluidly couples the gas delivery system to the substrate support structure.

23. The semiconductor processing system as recited in claim 22, wherein the gas delivery system further comprising:
at least one precursor source; and
a remote plasma unit connected to the at least one precursor source, wherein the remote plasma unit fluidly couples the at least one precursor source to the showerhead.

24. A method of making a substrate support structure, comprising:
intermixing mixing an aluminum oxide (Al₂O₃) powder with an yttrium oxide (Y₂O₃) powder and an aluminum nitride (AlN) powder;
forming a powder compact from the intermixed aluminum oxide (Al₂O₃) powder, yttrium oxide (Y₂O₃) powder, and aluminum nitride (AlN) powder;
sintering the powder compact for a predetermined sintering period at a predetermined sintering temperature and a predetermined sintering pressure; and
cooling the sintered powder compact to form a ceramic composite comprising two or more constituents selected from a group including (a) an aluminum nitride (AlN) constituent, (b) an aluminum oxynitride (Al_{2.81}O_{3.56}N_{0.44}, AlON) constituent, (c) an alpha-alumina (α-Al₂O₃) constituent, (d) a yttrium alumina garnet (Y₃Al₅O₁₂, YAG) constituent, (e) a yttrium alumina monoclinic (Y₄Al₂O₉, YAM) constituent, (f) a yttrium alumina perovskite (YAlO₃, YAP) constituent, and (g) a yttrium oxide (Y₂O₃) constituent.

25. The method of claim 24, wherein the powder compact comprises between about 0.02 Mol % and about 85 Mol % aluminum oxide (Al₂O₃), wherein the powder compact comprises between about 10 Mol % and about 65 Mol % yttrium oxide (Y₂O₃), and wherein the powder compact comprises between about 5 Mol % and about 65 Mol % aluminum nitride (AlN).

26. The method of claim 24, wherein the predetermined sintering temperature is between about 1500° C. and about 1750° C., or between about 1525° C. and about 1725° C., or between about 1550° C. and about 1700° C.
